(19) United States
(12) Patent Application Publication
(10) Pub. No.: US 2025/0069871 A1
(43) Pub. Date: Feb. 27, 2025

(54) SENSOR APPARATUS, PLASMA PROCESSING APPARATUS INCLUDING THE SAME, AND MANUFACTURING METHOD OF SEMICONDUCTOR DEVICE USING THE SAME

(71) Applicant: SAMSUNG ELECTRONICS CO., LTD., Suwon-si (KR)

(72) Inventors: Jonghwa LEE, Suwon-si (KR); Jawon KO, Suwon-si (KR); Taijo JEON, Suwon-si (KR); Yunsong JEONG, Suwon-si (KR)

(73) Assignee: SAMSUNG ELECTRONICS CO., LTD., Suwon-si (KR)

(21) Appl. No.: 18/597,432

(22) Filed: Mar. 6, 2024

(30) Foreign Application Priority Data
Aug. 22, 2023 (KR) 10-2023-0110019

(51) Int. Cl. H01J 37/32; G01J 3/28; H01L 21/66

(52) U.S. Cl. CPC H01J 37/32972; G01J 3/28; H01J 37/32642; H01J 37/32724; H01L 22/26; H01J 2237/2007; H01J 2237/202; H01J 2237/2445; H01J 2237/24585; H01J 2237/334

(57) ABSTRACT

A sensor apparatus for analyzing plasma in a plasma processing chamber, includes: a first substrate; a second substrate on the first substrate; and a plurality of sensors between the first substrate and the second substrate, the plurality of sensors being spaced apart from each other, wherein each of the plurality of sensors includes: (a) a sensing assembly that includes: (i) a wavelength selector on which light emitted from the plasma is incident and that is configured to separate wavelengths of a spectrum of the light, and (ii) a spectrometer that is optically connected to the wavelength selector and that is configured to detect the spectrum for each separated wavelength; and (b) a battery connected to the sensing assembly and configured to supply first power to the sensing assembly.

### CROSS-REFERENCE TO RELATED APPLICATION

This application is based on claims priority under 35 U.S.C. § 119 to Korean Patent Application No. 10-2023-0110019, filed on Aug. 22, 2023, in the Korean Intellectual Property Office, the disclosure of which is incorporated by reference herein in its entirety.

### BACKGROUND

### 1. Field

The disclosure relates to a sensor apparatus, a plasma processing apparatus including the same, and a manufacturing method of a semiconductor device using the same.

### 2. Description of the Related Art

Semiconductor devices may be manufactured by various semiconductor manufacturing processes, such as an etching process, a deposition process, an ashing process, and a cleaning process. Particularly, a process using plasma has been applied to a semiconductor manufacturing process.

Efforts have been made to analyze characteristics of plasma within the process chamber in a process apparatus using plasma. In a method of related art, in order to check for abnormalities in a plasma process, an optical emission spectroscopy (OES) is used, which analyzes light emitted through a view port provided at a point on one side surface of a process chamber. However, the method of the related art is only an one-dimensional analysis of the emission spectrum and is mainly used only for end point detection (EPD) purposes.

Therefore, there is a need to develop an apparatus and a method for more effectively analyzing the characteristics of the plasma within the plasma process chamber.

### SUMMARY

Provided is a sensor apparatus that may effectively detect characteristics of plasma within a plasma process chamber.

Provided is a plasma apparatus that may effectively detect characteristics of plasma within a plasma process chamber and may actively control a plasma density through this.

Provided is a manufacturing method of a semiconductor device using a sensor apparatus that may effectively detect characteristics of plasma in a plasma process chamber and a plasma processing apparatus including the same.

According to an aspect of the disclosure, a sensor apparatus for analyzing plasma in a plasma processing chamber, includes: a first substrate; a second substrate on the first substrate; and a plurality of sensors between the first substrate and the second substrate, the plurality of sensors being spaced apart from each other, wherein each of the plurality of sensors includes: (a) a sensing assembly that includes: (i) a wavelength selector on which light emitted from the plasma is incident and that is configured to separate wavelengths of a spectrum of the light, and (ii) a spectrometer that is optically connected to the wavelength selector and that is configured to detect the spectrum for each separated wavelength; and (b) a battery connected to the sensing assembly and configured to supply first power to the sensing assembly.

According to an aspect of the disclosure, a plasma processing apparatus includes: a chamber in which plasma is generated; a support portion supporting an object to be processed through the plasma generated in the chamber; a head portion in the chamber, the head portion being configured to face the support portion; a sensor apparatus between the support portion and the head portion, the sensor apparatus including a plurality of sensors respectively arranged at a plurality of points spaced apart from each other, wherein the support portion is configured to support the sensor apparatus; and wherein each of the plurality of sensors includes: a spectrometer configured to detect a spectrum of light emitted from the plasma at a point where the each of the plurality of sensors is disposed, and a battery configured to supply first power to the spectrometer.

According to an aspect of the disclosure, a manufacturing method performed by a semiconductor device, includes: disposing a sensor apparatus arranged with a plurality of sensors that is configured to detect plasma density in a chamber of a process apparatus that is configured to perform a plasma process; detecting plasma density at a plurality of points at which the plurality of sensors are disposed in the sensor apparatus; controlling the plasma density at the plurality of points by controlling the process apparatus; replacing the sensor apparatus within the chamber with a wafer; and performing the plasma process on the wafer.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 illustrates a plasma processing apparatus according to an embodiment;

FIG. 2 illustrates a perspective view of a sensor apparatus according to an embodiment;

FIG. 3 illustrates a top plan view of a sensor apparatus according to an embodiment;

FIG. 4 illustrates a partial cross-sectional view of a sensor apparatus according to an embodiment;

FIG. 5 illustrates an exploded view of FIG. 4;

FIG. 6 illustrates a sensor of a sensor apparatus according to an embodiment;

FIG. 7 illustrates a partial cross-sectional view of a sensor apparatus according to another embodiment;

FIG. 8 illustrates a top plan view of a sensor apparatus according to another embodiment;

FIG. 9 to FIG. 11 illustrate plasma densities analyzed through a sensor apparatus according to an embodiment; and

FIG. 12 to FIG. 15 illustrate operations of controlling a plasma processing apparatus according to an embodiment.

### DETAILED DESCRIPTION

The disclosure will be described more fully hereinafter with reference to the accompanying drawings, in which embodiments of the disclosure are shown. As those skilled in the art would realize, the described embodiments may be modified in various different ways, all without departing from the spirit or scope of the disclosure.

In order to clearly describe the disclosure, parts that are irrelevant to the description are omitted, and identical or similar constituent elements throughout the specification are denoted by the same reference numerals.

Further, in the drawings, the size and thickness of each element are arbitrarily illustrated for ease of description, and the disclosure is not necessarily limited to those illustrated in the drawings.

Throughout this specification and the claims that follow, when it is described that an element is “coupled or connected” to another element, the element may be “directly coupled or connected” to the other element or “indirectly coupled or connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” refers to any device, system, or part thereof that controls at least one operation. Such a controller may be implemented in hardware or a combination of hardware and software and/or firmware. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. The expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Hereinafter, a plasma processing apparatus according to an embodiment will be described with reference to the accompanying drawings.

In this specification, the term “plasma process” means all of performing specific treatment on a substrate (for example, a wafer) to be processed using plasma. For example, it includes all processes using plasma in a semiconductor manufacturing process, such as a deposition process, a cleaning process, an ashing process, and an etching process. The following description mainly focuses on an etching process among plasma processes for convenience of understanding. However, the following description is not limited to the etching process, and may also be applied to other plasma processes other than the etching process.

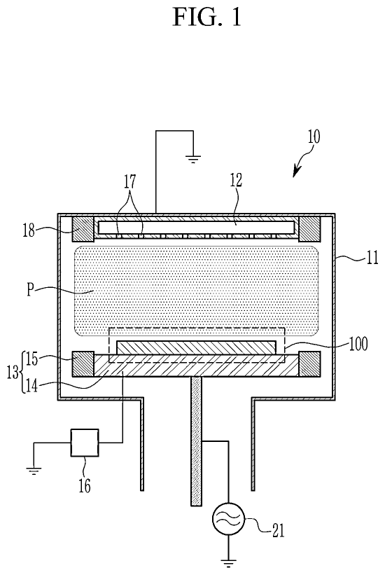

FIG. 1 illustrates a plasma processing apparatus according to an embodiment. In FIG. 1, the plasma processing apparatus is schematically illustrated and is illustrated in a cross-sectional view.

A plasma processing apparatus 10 according to an embodiment may perform an etching of a film to be etched on a substrate (for example, a wafer) disposed in a chamber 11. The plasma processing apparatus 10 of the embodiment is not limited to an etching apparatus, but may also be a deposit apparatus, an ashing apparatus, and a cleaning apparatus.

Plasma P generated in the plasma processing apparatus 10 of the embodiment is illustratively described as capacitively coupled plasma (CCP), but is not limited thereto, and may be inductively coupled plasma (ICP) or microwave plasma.

Referring to FIG. 1, the plasma processing apparatus 10 of the embodiment includes the chamber 11, a support portion 13, a head portion 12, and a sensor apparatus 100.

The chamber 11 may provide an inner area in which a plasma treatment process for a substrate (a wafer) to be treated is performed. The plasma P is generated in the inner area, so that a plasma process may be performed on the substrate wafer. The chamber 11 is closed and sealed from outside so that a vacuum state may be maintained. A gate may be provided on a side wall of the chamber 11 for entry and exit of a substrate (for example, a wafer or a sensor apparatus of an embodiment), which is an object to be processed.

A discharge line for discharging gas may be connected to one lower portion of the chamber 11, and the discharge line may be connected to a vacuum pump. The chamber 11 may have a cylindrical shape, but its shape is not limited thereto. The chamber 11 may include at least one of a metal and an insulator.

The support portion 13 may be disposed within the chamber 11 to support an object to be treated through the plasma P. The support portion 13 may be disposed at a lower portion of the inner area of the chamber 11. The support portion 13 may have a disk shape with a larger diameter than the object to be processed (for example, a wafer or a sensor apparatus of an embodiment) to be supported on the support portion 13, but is not limited thereto.

According to the embodiment, the support portion 13 may be driven in a vertical direction (a direction of approaching or moving away from the head portion, which will be described later, hereinafter referred to as a ‘first direction’). Referring to FIG. 1, the support portion 13 may be connected to a driver 16, and may move in the first direction by the driver 16. Accordingly, the object to be processed supported on the support portion 13 may be brought closer to or away from the head portion 12, which will be described later.

Referring to FIG. 1, the support portion 13 may include a chuck 14 and an edge ring 15. The chuck 14 may fix the object to be processed. In an embodiment, the chuck 14 may include an electrostatic chuck that adsorbs the object to be processed with electrostatic force. The edge ring 15 may control the plasma, and may be disposed to surround an outside of the chuck 14. The chuck 14 and the edge ring 15 described above may be individually driven in the first direction by the driver 16. According to the embodiment, the plasma density may be adjusted by driving the chuck 14 and the edge ring 15, which will be described later.

According to the embodiment, the chuck 14 may include a heater for heating the supported object to be processed. In an embodiment, when a plasma process is performed within the chamber 11 while a wafer is supported on an upper surface of the chuck 14, the wafer may be heated to a temperature suitable for the plasma process through the heater built into the chuck 14. A temperature of the wafer may be controlled differently depending on a partitioned area, and the plasma density may vary depending on the controlled temperature, which will be described later.

According to the embodiment, a power supply 21 may be connected to the support portion 13. For example, the power supply 21 may be a radio frequency (RF) power supply for generating and controlling the plasma P. Accordingly, RF power for plasma generation may be supplied from the power supply 21 to the support portion 13. Accordingly, the support portion 13 may be a lower electrode that generates plasma. In this case, an upper electrode corresponding to the lower electrode may be the head portion 12, which will be described later. Accordingly, the plasma P is generated in the area between the head portion 12, which is the upper electrode, and the support portion 13, which is the lower electrode, and the object to be processed disposed between the head portion 12 and the support portion 13 may be processed by the generated plasma P.

The head portion 12 is disposed within the chamber 11. The head portion 12 may be disposed to face the support portion 13 described above with the object to be processed therebetween. The head portion 12 can be disposed at an upper portion of the inner area of the chamber 11. The head portion 12 may have a disk shape, but is not limited thereto.

According to one embodiment, the head portion 12 may have a plurality of through holes 17 through which gas that generates plasma is injected into the inner area of the chamber 11. Gas that generates plasma may be supplied onto the object to be processed supported on the support portion 13 through the plurality of through holes 17. For example, referring to FIG. 1, the head portion 12 may have a hollow interior, and may be provided with a plurality of through holes 17 on one side facing the support portion 13. In some embodiments, the head portion 12 may be connected to a gas supply source to supply gas into the head portion 12.

According to the embodiment, the plurality of through holes 17 are divided into a plurality of areas, and a gas injection amount may be individually adjusted in each of the plurality of divided areas. The plasma density may vary depending on the gas injection amount. Related details will be described later.

Referring to FIG. 1, an upper ring 18 surrounding the outside of the head portion 12 may be disposed at the upper portion of the inner area of the chamber 11.

As described above, the head portion 12 may be an upper electrode for generating the plasma P. In an embodiment, the power supply 21 is connected only to the support portion 13 and not to the head portion 12, but is not limited thereto, and a separate power supply may be connected to each of the support portion 13 and the head portion 12. In an embodiment, the power supply may be connected only to the head portion 12 and not to the support portion 13.

In the embodiment, the plasma processing apparatus 10 includes the sensor apparatus 100 between the head portion 12 and the support portion 13. According to the embodiment, the sensor apparatus 100 may be disposed to replace the object to be processed on the support portion 13 on which the object to be processed through the plasma process is supported. The sensor apparatus 100 may analyze plasma within the chamber 11 of the plasma processing apparatus 10. Hereinafter, the sensor apparatus 100 according to the embodiment will be described in detail.

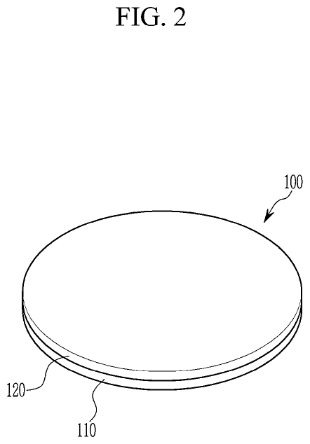

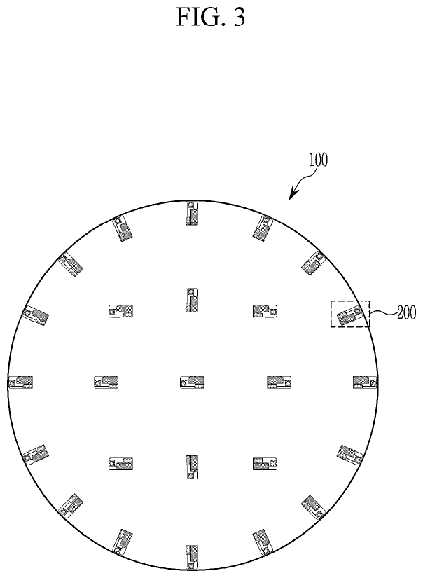

FIG. 2 illustrates a perspective view of a sensor apparatus according to an embodiment. FIG. 3 illustrates a top plan view of a sensor apparatus according to an embodiment.

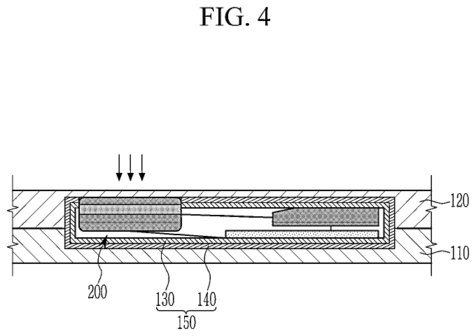

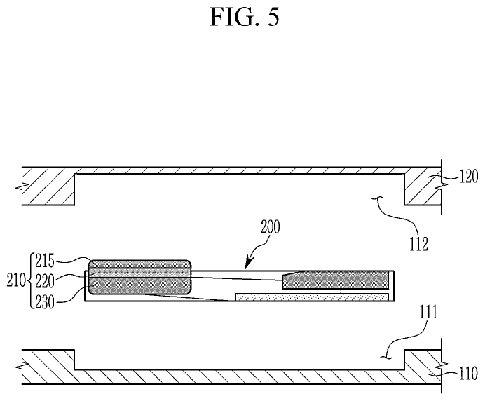

For ease of understanding, FIG. 2 exaggerates a thickness, and FIG. 3 shows a perspective view so that an inner sensor is visible. FIG. 4 illustrates a partial cross-sectional view of a sensor apparatus according to an embodiment, and FIG. 5 illustrates an exploded view of FIG. 4.

In FIG. 5, for better comprehension, for ease of understanding, some components (for example, a blocking layer and the like) are excluded.

Referring to FIG. 1, the sensor apparatus 100 of the embodiment may be supported by the support portion 13. The sensor apparatus 100 may be supported on the support portion 13 by replacing the object to be processed (for example, wafer) through a plasma process.

In an embodiment, the sensor apparatus 100 may be a type of dummy wafer. Referring to FIG. 2, the sensor apparatus 100 may have the same shape on a plane as the wafer, which is an object to be processed in the plasma processing apparatus 10. For example, the sensor apparatus 100 may have a disk shape. For example, the sensor apparatus 100 may have a diameter of 300 mm, but is not limited thereto, and may have a diameter of a typical semiconductor manufacturing wafer, such as 150 mm or 200 mm. In some embodiments, as another shape, the sensor apparatus 100 may have a quadrangular substrate shape. However, for better understanding and ease of description, in the following description, the sensor apparatus 100 having a disc shape like a wafer will be described as an example.

The sensor apparatus 100 may have a very small thickness compared to a diameter of the sensor apparatus 100. For example, the sensor apparatus 100 may have a thickness of about 2 mm, but is not limited thereto.

Referring to FIG. 2 to FIG. 5, the sensor apparatus 100 of the embodiment may include a first substrate 110, a second substrate 120, and a plurality of sensors 200. Referring to FIG. 2 and FIG. 4, the sensor apparatus 100 may have a structure in which the plurality of sensors 200 are embedded (disposed or provided) between the first substrate 110 and the second substrate 120 that are stacked together. Referring to FIG. 3, the sensor apparatus 100 may include a plurality of sensors 200 each disposed at a plurality of points arranged to be spaced apart from each other in a plan view.

The first substrate 110 may have a disc shape, and may be made of a material similar to a wafer. For example, the first substrate 110 may include silicon (Si). Referring to FIG. 4 and FIG. 5, the first substrate 110 may have a plurality of first grooves 111 on one surface in contact with the second substrate 120, which will be described later. The plurality of first grooves 111 may accommodate at least some of the plurality of sensors 200, which will be described later.

The second substrate 120 may be stacked on the first substrate 110 to be bonded to the first substrate 110. The second substrate 120 may have a disk shape with the same diameter as the first substrate 110.

In some embodiments, the second substrate 120 may be made of a transparent material. Accordingly, the second substrate 120 may transmit light emitted from the plasma (P). For example, the second substrate 120 may be a glass substrate. For example, the second substrate 120 may include quartz or sapphire glass (Al₂O₃). For example, the second substrate 120 may include a material that transmits light in the range of 200 to 1000 nm, which is the wavelength of light generated in the etching process.

Referring to FIG. 5, the first substrate 110 may have a plurality of first grooves 111 on or near one surface of the first substrate 110. A plurality of second grooves 112 may be disposed on or near one surface of the second substrate 120 to face the plurality of first grooves 111. In other words, the plurality of first grooves 111 and the plurality of second grooves 112 may be disposed at positions corresponding to each other. The plurality of second grooves 112 may accommodate (include or provide) at least some of the plurality of sensors 200, which will be described later. According to the embodiment, each of the plurality of sensors 200 may be accommodated (disposed, provided, or placed) in an area defined by one first groove 111 and the second groove 112 at a corresponding position thereto.

The plurality of sensors 200 may be embedded between the first substrate 110 and the second substrate 120. Referring to FIG. 3, the plurality of sensors 200 may be arranged to be spaced apart from each other in a plan view. In a plan view, the plurality of sensors 200 may be respectively disposed at a plurality of points arranged to be spaced apart from each other.

According to the embodiment, each of the plurality of sensors 200 may detect a spectrum of light emitted from the plasma (P). By respectively disposing the plurality of sensors 200 at a plurality of points arranged to be spaced apart from each other in a plan view, the density of plasma at the plurality of points may be detected.

According to the embodiment, each of the plurality of sensors 200 may be surrounded by a blocking layer 150. The blocking layer 150 may protect the sensors 200 from external influences such as heat or electromagnetic waves generated during the plasma process. The blocking layer 150 may cover a front surface of each of the plurality of sensors 200. However, a portion on which light is incident among each of the sensors 200 may not be covered by the blocking layer 150.

Referring to FIG. 4, the blocking layer 150 may include a first blocking layer 130 and a second blocking layer 140. For example, the first blocking layer 130 may block electromagnetic waves or radio frequency (RF). The second blocking layer 140 may block heat. FIG. 4 shows a structure in which the second blocking layer 140 is disposed on the first blocking layer 130, but the structure is not limited thereto, and the positions of the first blocking layer 130 and the second blocking layer 140 may be interchanged.

As an example, the blocking layer 150 may be formed by covering an outer surface of the sensors 200 with a thin film-type material. As another example, the blocking layer 150 may be formed by spraying a liquid material on an outer surface of the sensors 200. However, the method of forming the blocking layer 150 is not limited thereto.

According to the embodiment, the plurality of sensors 200 may be disposed to be denser from a central portion to an edge portion of a substrate in which the first substrate 110 and the second substrate 120 are combined in a plan view (hereinafter referred to as a ‘combined substrate’). According to another embodiment, the plurality of sensors 200 may be radially disposed on the plane of the combined substrate. According to another embodiment, the plurality of sensors 200 may be disposed on a concentric circle around a center point of the combined substrate in a plan view. According to another embodiment, the plurality of sensors 200 may be symmetrically disposed with respect to the center point of the combined substrate in a plan view. The plurality of sensors 200 are not limited to the above-described disposition structures, and may be variously disposed.

According to the embodiment, each of the plurality of sensors 200 may detect a spectrum of light emitted from the plasma (P). The plurality of sensors 200 may all have the same configuration. Hereinafter, a configuration of one of the plurality of sensors 200 will be described in detail.

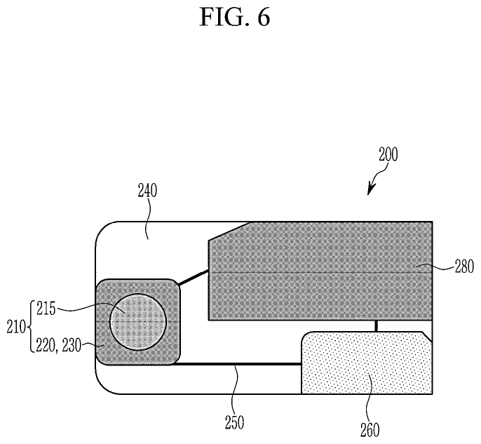

FIG. 6 illustrates a sensor of a sensor apparatus according to an embodiment. FIG. 6 is shown as a top plan view and as a schematic view for ease of understanding.

Referring to FIG. 6, the sensor 200 may include a sensing assembly 210 and a battery 280. According to the embodiment, the sensor 200 may further include a controller 260. According to the embodiment, the sensor 200 has a thin shape because it may be embedded between the first substrate 110 and the second substrate 120, which have a wafer-like shape. For example, a thickness of the sensor 200 may be 2 mm or less.

According to the embodiment, components of the sensors 200 (the sensing assembly, the battery, and the controller) may be disposed on a base 240. The base 240 may be a thin-plate or thin-film circuit board, but is not limited thereto. The components of the sensors 200 may be electrically connected to each other through a wire 250 on the base 240. In some embodiments, the sensors 200 may further include a housing for accommodating components. In some embodiments, a sealant that seals the components of the sensors 200 may be further included.

The sensing assembly 210 may detect the spectrum of light emitted from the plasma P. According to the embodiment, the sensing assembly 210 may include an optical member 215, a wavelength selector 220, and a spectrometer 230. The components configuring the sensing assembly 210, for example, the optical member 215, the wavelength selector 220, and the spectrometer 230, may be optically or electrically connected to each other.

The optical member 215 is a portion on which light emitted from the plasma P is incident. The optical member 215 may include at least one optical element for collecting and transmitting light. For example, the optical member 215 may include a lens. For example, the optical member 215 may include an optical fiber.

The wavelength selector 220 may separate a wavelength of a spectrum of light incident through the optical member 215.

According to the embodiment, the wavelength selector 220 may include a grating. In an embodiment, the wavelength selector 220 may separate the wavelengths of the light spectrum through a grating in which a plurality of grooves or protrusions are arranged on one surface of a mirror.

According to another embodiment, the wavelength selector 220 may include a plasmonic color filter. In an embodiment, the wavelength selector 220 may separate wavelengths of the light spectrum through a plasmonic color filter having a pattern in which a plurality of negative or positive angles are arranged. When the wavelength selector 220 includes a plasmonic color filter, the sensing assembly 210 may be manufactured to have a very thin thickness, and the sensing assembly 210 may be implemented in the form of a lap on a chip.

The spectrometer 230 may detect a spectrum with the separated wavelengths through the wavelength selector 220 described above. The spectrum with the separated wavelengths through the wavelength selector 220 is incident on the spectrometer 230, and the spectrometer 230 may detect the spectrum for all wavelengths. Accordingly, the state of plasma at the point at which the sensors 200 is disposed may be analyzed using the spectrum signal detected by the spectrometer 230. In addition, the state of plasma, for example, the density of plasma, at the plurality of points may be analyzed using the spectrum signals respectively detected by the plurality of sensors 200 arranged at the plurality of points.

The battery 280 may be connected to the sensing assembly 210 to supply power to the sensing assembly 210. According to the embodiment, the battery 280 may be disposed on the base 240, and the battery 280 and the sensing assembly 210 may be connected through the wire 250 on the base 240.

The battery 280 may have a thin thickness. According to the embodiment, the battery 280 may include a thin film battery.

The battery 280 may be configured to enable wireless charging. Accordingly, the battery 280 of the sensors 200 does not need to be replaced, and may be wirelessly charged if necessary. Since the sensors 200 are embedded between the first substrate 110 and the second substrate 120, the battery 280 in the sensors 200 may be wirelessly charged using a wireless charging device outside the first substrate 110 or the second substrate 120.

The controller 260 is configured to store and communicate information detected by the spectrometer 230. The controller 260 may be connected to the sensing assembly 210 and the battery 280 through the wire 250. Accordingly, the controller 260 may be connected to the spectrometer 230, and may receive power through the battery 280.

According to the embodiment, the controller 260 may include a memory device for storing information transmitted from the spectrometer 230. According to the embodiment, the controller 260 may include a communication element (or part) including an antenna for wirelessly communicating information transmitted from the spectrometer 230 to outside of the chamber 11. The controller 260 may transmit the stored information data to an output device provided separately outside the chamber 11 through a wireless communication such as Bluetooth.

The external output device described above may map the plasma density inside the chamber 11 into a wafer shape (that is, the shape of the sensor apparatus) by calculating the transmitted data using software.

As described above, each of the sensors 200 is embedded between the first substrate 110 and the second substrate 120, and may have the same diameter as the wafer and a thin thickness. The sensors 200 includes the sensing assembly 210 that detects the spectrum of light emitted from plasma and the battery 280 that supplies power to the sensing assembly 210, and additionally, it may include the controller 260 that receives and stores the spectrum information detected by the sensing assembly 210 and communicates with the outside. Each sensors 200 may detect the spectrum of plasma incident on the point at which each sensors 200 is disposed, and analyze the state of the plasma using the detected information.

In the embodiment, the sensor apparatus 100 can detect the plasma spectra at the plurality of points by dispersing and disposing the plurality of sensors 200 at the plurality of points. Through this, it may be possible to check the density of plasma depending on the position to detect points at which the density of plasma is relatively high or low. Using this detection information, the plasma processing apparatus may be actively controlled so that the density of the plasma P may be uniformly distributed within the chamber 11 of the plasma processing apparatus 10 of the embodiment or so that the density of the plasma P may be adjusted depending on the position.

Hereinafter, since the sensor apparatus 100 described above may be modified into various forms, another embodiment of the sensor apparatus 100 will be described.

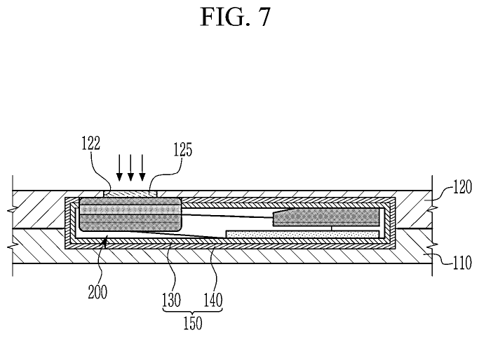

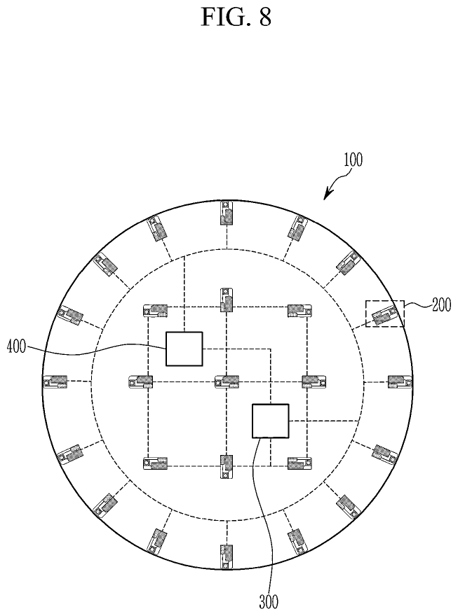

FIG. 7 illustrates a partial cross-sectional view of a sensor apparatus according to another embodiment. FIG. 8 illustrates a top plan view of a sensor apparatus according to another embodiment.

In the description of FIG. 7 and FIG. 8, the same content as in the embodiment described above will be omitted, and differences will be mainly described.

In the sensor apparatus of another embodiment illustrated in FIG. 7, the second substrate 120 may not be made of a transparent material, and may be made of a material similar to a wafer. For example, the second substrate 120 may be made of the same material as the first substrate 110, and may include silicon (Si).

Referring to FIG. 7, the second substrate 120 may have through holes 122 at positions corresponding to the plurality of sensors 200, respectively. Although only one sensor 200 is shown in FIG. 7, the through holes 122 may be disposed at positions corresponding to other sensors 200, respectively.

Referring to FIG. 7, a window 125 made of a transparent material may be inserted into one of the through holes 122. For example, the inside of the through hole 122 may be filled by melting a glass material. Accordingly, light emitted from the plasma P may be incident on the sensors 200 through the window 125 filled in the through hole 122. According to the embodiment, the window 125 may include a material that transmits light with a wavelength in the range of 200 to 1000 nm. In the case of the embodiment shown in FIG. 7, there may be no need to manufacture the second substrate 120 from a transparent material, and thus, the first substrate 110 and the second substrate 120 may be manufactured from the same material.

Referring to FIG. 8, the sensor apparatus 100 of another embodiment may include an integrated controller 300 disposed on a combined substrate (or at least one of the first substrate 110 and the second substrate 120). Here, the integrated controller 300 may be provided separately from the controller 260 included in one sensor 200 in the above-described embodiment.

In some embodiments, each of the plurality of sensors 200 includes the controller 260, but the separate integrated controller 300 may be further provided.

In some embodiments, when the separate integrated controller 300 is provided, each sensors 200 may not include the controller 260. Accordingly, storage (and/or communication) of information detected by each sensors 200 may be performed by the integrated controller 300.

The integrated controller 300 may be electrically connected to the plurality of sensors 200. The integrated controller 300 may store (and/or communicate) information detected by the plurality of sensors 200. The integrated controller 300 may be embedded within the combined substrate.

Referring to FIG. 8, the sensor apparatus 100 of another embodiment may include a power supply 400 disposed on a combined substrate (or at least one of the first substrate 110 and the second substrate 120). Here, the power supply 400 may be provided separately from the battery 280 included in one sensor 200 in the above-described embodiment.

For example, each of the plurality of sensors 200 includes the battery 280, but the separate power supply 400 may be further provided.

As another example, when the separate power supply 400 is provided, each sensors 200 may not include the battery 280. Accordingly, power supply to each sensors 200 may be performed from the power supply 400.

The power supply 400 may be electrically connected to the plurality of sensors 200. The power supply 400 may directly supply power to the plurality of sensors 200 or may supply power to the battery 280 provided in each sensors 200. The power supply 400 may be configured to enable wireless charging. The power supply 400 may be embedded in the combined substrate.

Referring to FIG. 8, the controller 300 and the power supply 400 described above may be electrically connected to the plurality of sensors 200. For example, the combined substrate (or at least one of the first substrate 110 and the second substrate 120) may include a plurality of wire layers, and the controller 300 and the power supply 400 may be electrically connected to the plurality of sensors 200 through the plurality of wire layers.

Hereinafter, analyzing plasma density using the sensor apparatus 100 of an embodiment disposed within the plasma processing apparatus 10 will be described.

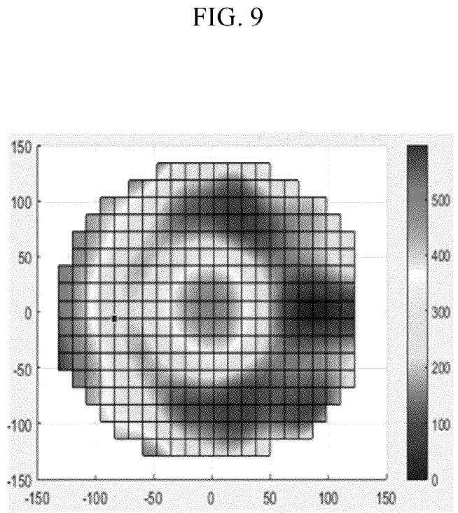

FIG. 9 to FIG. 11 illustrate plasma densities analyzed through a sensor apparatus according to an embodiment.

FIG. 9 illustrates mapping the plasma density on the sensor apparatus 100 into a two-dimensional plan view using spectrum information respectively detected by the plurality of sensors 200 of the sensor apparatus 100 according to the embodiment. In FIG. 9, the left and lower coordinate axes illustrate positions, respectively, and the right is a legend showing the density of plasma in color and relative values. In FIG. 9, the circular shape illustrated on the coordinate axis is mapping of the density of plasma according to the position on the sensor apparatus 100 to the planar shape of the sensor apparatus 100.

Referring to FIG. 9, the plasma density was high in the central portion and the left edge portion of the sensor apparatus 100 in a plan view. Since the sensor apparatus 100 of the embodiment has the same shape as the wafer that is the object to be processed in the plasma processing apparatus 10, when performing a plasma process on the wafer through the plasma processing apparatus 10, it may be expected that the same plasma density as in FIG. 9 appears. Accordingly, the plasma process may be improved by controlling the plasma processing apparatus 10 so that the plasma density appears uniformly.

Since the plurality of sensors 200 included in the sensor apparatus 100 of the embodiment may wirelessly communicate the detected information with the outside, from the outside, the density of the plasma P in the plasma processing apparatus 10 may be monitored in real time. For example, the plasma processing apparatus 10 may be controlled so that the plasma density appears uniformly while monitoring the plasma density in real time using information detected by the sensor apparatus 100.

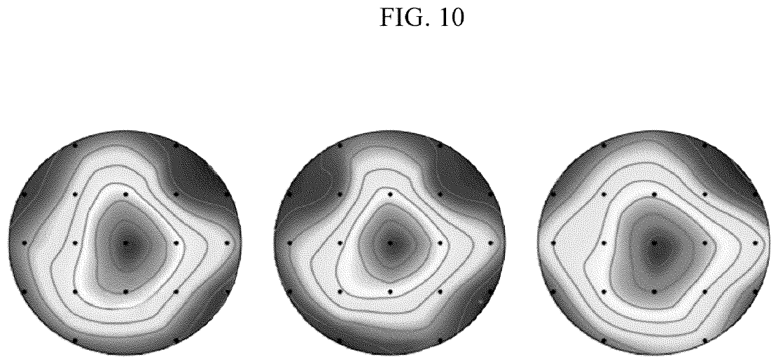

FIG. 10 illustrates the plasma density on the sensor apparatus 100 mapped into a two-dimensional plan view changing over time. In the three pictures in FIG. 10, the direction from left to right is the direction of time flow. In each of the three pictures in FIG. 10, the black dot represents the point at which the plurality of sensors 200 are disposed.

Referring to FIG. 10, the plasma density on the sensor apparatus 100 is changing from the left picture to the right picture. Therefore, before proceeding with the plasma process on the actual wafer, by controlling the plasma processing apparatus 10 so that the plasma density analyzed through the sensor apparatus 100 appears uniformly, the plasma process for the actual wafer may be improved.

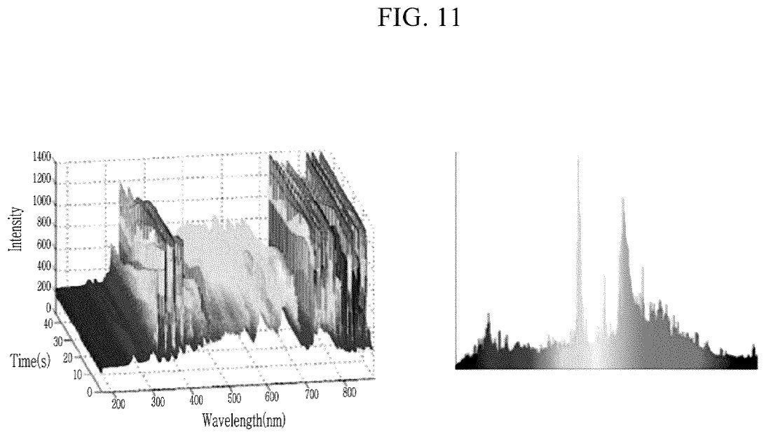

FIG. 11 illustrates a mapping of the plasma density (intensity) at one point on the sensor apparatus 100 using spectral information detected by one sensor 200 disposed at one point in the sensor apparatus 100 of the embodiment. That is, FIG. 11 illustrates the plasma density (intensity) mapped using the spectrum information detected at one of the plurality of points indicated by black dots in the picture of FIG. 10. The left picture of FIG. 11 illustrates the plasma density (intensity) on the sensor apparatus 100 mapped in three dimensions according to wavelength and time. That is, the results of 3D (time, wavelength, and intensity) OES may be detected using the embodiment. The right picture of FIG. 11 illustrates the plasma density (intensity) mapped in two dimensions according to wavelength.

Referring to the left picture of FIG. 11, the density of plasma is high in the 350 to 450 nm and 750 to 900 nm wavelength ranges at one point in the sensor apparatus 100 of the embodiment. Therefore, before proceeding with the plasma process on the actual wafer, by controlling the injection amount of gas components representing a specific wavelength range among the gases injected into the plasma processing apparatus 10, the plasma process for the actual wafer may be improved.

Hereinafter, a manufacturing method of a semiconductor device according to an embodiment will be described.

Referring to FIG. 1, first, the sensor apparatus 100 of the embodiment is disposed in the chamber 11 of the plasma processing apparatus 10. Here, in the sensor apparatus 100, a plurality of sensors 200 for detecting plasma density are arranged at a plurality of points in a plan view. The sensor apparatus 100 is supported on the support portion 13 or the chuck 14, and the plasma processing apparatus 10 is operated. During the plasma process, the sensor apparatus 100 may detect the plasma density at the plurality of points where the plurality of sensors 200 are disposed. In this case, the output device outside the chamber may wirelessly communicate with the plurality of sensors 200 to map the plasma density information at the plurality of points in real time. The detected (or mapped) plasma density is checked, and thus, the plasma processing apparatus 10 is controlled to adjust the plasma density at the plurality of points. In this case, the plasma processing apparatus 10 may be controlled simultaneously while monitoring the plasma density at the plurality of points in real time.

When monitoring the detected plasma density, if a serious abnormality (that is difficult to control) is found, the plasma processing apparatus 10 may be stopped.

After controlling the plasma processing apparatus 10 to adjust the plasma density, the plasma process is stopped. Thereafter, the sensor apparatus 100 is removed from the plasma processing apparatus 10, and the wafer on which the actual semiconductor device is to be manufactured is supported on the support portion 13 or the chuck 14. In other words, the sensor apparatus 100 is replaced with a wafer, which is the object to be processed. Then, a plasma process is performed on the wafer.

In the operation of controlling the plasma density in the manufacturing method of the semiconductor device described above, by controlling at least one of a distance between the chuck 14 and the head portion 12 where the plasma P is generated, a temperature of the chuck 14, a position of the edge ring 15 surrounding the chuck 14, and an injection amounts of gas injected from the head portion 12, the plasma density may be controlled.

Specifically, the plasma process for wafers may be improved by using the plasma processing apparatus 10 including the sensor apparatus 100 according to the embodiment.

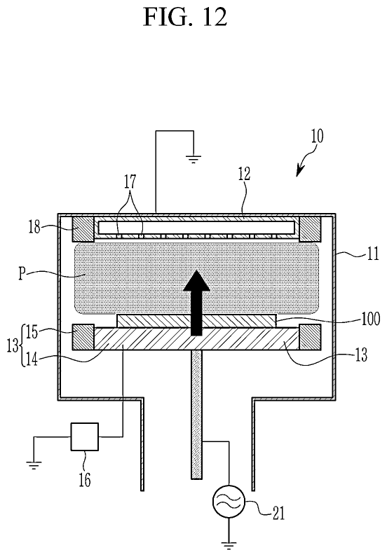

FIG. 12 to FIG. 15 illustrate operations for controlling a plasma processing apparatus according to an embodiment.

Referring to FIG. 12, the plasma density may be controlled by moving the support portion 13, specifically the chuck 14, supporting the sensor apparatus 100 of the embodiment in the first direction (a direction closer to or farther away from the head portion). For example, by moving the chuck 14 in a direction closer to the head portion 12, when the area in which the plasma P is generated becomes smaller, the density of the plasma P may increase.

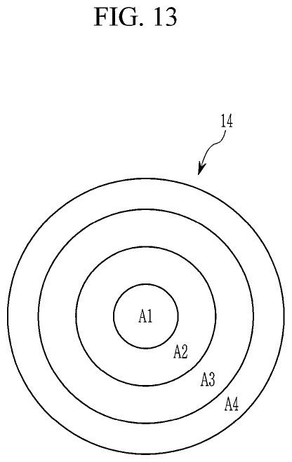

FIG. 13 shows the chuck 14 in a plan view. According to an embodiment, the chuck 14 is partitioned into a plurality of areas A1 to A4 in a plan view, and the temperature of each of the plurality of areas A1 to A4 may be individually controlled. Accordingly, by controlling the temperature of the chuck 14, the plasma density may be controlled. For example, the density of the plasma P may be lowered on an area with a high temperature among the plurality of areas A1 to A4 of the chuck 14. FIG. 13 illustrates the chuck 14 partitioned into four areas. However, the chuck is not limited thereto. The chuck 14 may be partitioned into smaller or more areas.

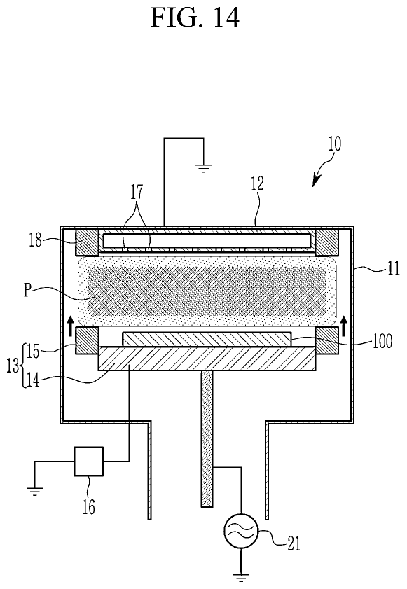

Referring to FIG. 14, the plasma density may be controlled by moving the edge ring 15 surrounding the outside of the chuck 14 in the first direction. The driver 16 connected to the support portion 13 may drive the chuck 14 and the edge ring 15 simultaneously or individually. For example, when the edge ring 15 is moved closer to the head portion 12, the density of the plasma P at the edge portion of the object to be processed may be lowered.

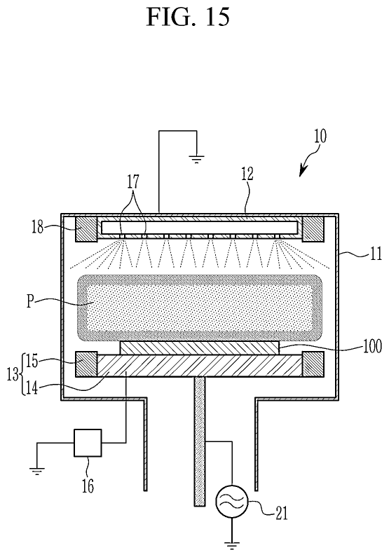

Referring to FIG. 15, the plasma density may be controlled by controlling the injection amount of gas injected into the chamber 11 through the head portion 12. The head portion 12 has the plurality of through holes 17 for injecting the gas that generates the plasma P into the chamber 11. According to the embodiment, the plurality of through holes 17 are partitioned into a plurality of areas in a plan view, and the injection amount of gas may be individually controlled for each of the plurality of areas. Thus, the plasma density may be controlled by controlling the injection amount of gas for each area. For example, the density of the plasma P may increase in an area with a large amount of gas injection.

The plasma density control method described through FIG. 12 to FIG. 15 is only an example, but is not limited thereto. The plasma density control method may vary depending on the type or structure of the plasma processing apparatus.

While this disclosure has been described in connection with what is presently considered to be practical embodiments, the disclosure is not limited to the disclosed embodiments. The disclosure is intended to cover various modifications and equivalent arrangements included within the spirit and scope of the appended claims.

What is claimed is:

1. A plasma processing apparatus comprising:
a chamber in which plasma is generated;
a support portion supporting an object to be processed through the plasma generated in the chamber;
a head portion in the chamber, the head portion being configured to face the support portion; and
a sensor apparatus between the support portion and the head portion, the sensor apparatus comprising:
a first substrate;
a second substrate on the first substrate; and
a plurality of sensors between the first substrate and the second substrate, the plurality of sensors being spaced apart from each other, wherein each of the plurality of sensors includes:
a sensing assembly that includes a wavelength selector on which light emitted from the plasma is incident and that is configured to separate wavelengths of a spectrum of the light, and a spectrometer that is optically connected to the wavelength selector and configured to detect the spectrum for each separated wavelength; and
a battery connected to the sensing assembly and configured to supply first power to the sensing assembly.

2. The plasma processing apparatus of claim 1, wherein the first substrate includes a plurality of first grooves on one surface that contacts the second substrate,
wherein the second substrate includes a plurality of second grooves respectively facing the plurality of first grooves, and
wherein the each of the plurality of sensors is disposed in an area defined by each of the plurality of first grooves and each of the plurality of second grooves corresponding to the each of the plurality of first grooves.

3. The plasma processing apparatus of claim 1, wherein the second substrate is made of a transparent material that transmits light.

4. The plasma processing apparatus of claim 1, wherein the second substrate includes a through hole at each of positions corresponding to the plurality of sensors, and
wherein the through hole includes a transparent material.

5. The plasma processing apparatus of claim 1, wherein the each of the plurality of sensors further includes a controller connected to the spectrometer and configured to store detected information.

6. The plasma processing apparatus of claim 5, wherein the battery is connected to the controller, and configured to supply the first power to the controller.

7. The plasma processing apparatus of claim 1, further comprising a controller on at least one of the first substrate and the second substrate,
wherein the controller is electrically connected to the plurality of sensors and configured to store information detected by the plurality of sensors.

8. The plasma processing apparatus of claim 7, further comprising a power supply on at least one of the first substrate and the second substrate,
wherein the power supply is electrically connected to the plurality of sensors and is configured to supply second power to the plurality of sensors.

9. The plasma processing apparatus of claim 1, wherein the wavelength selector includes at least one of a plasmonic color filter or a grating.

10. The plasma processing apparatus of claim 1, wherein each of the plurality of sensors is covered by at least one of a heat blocking layer and an electromagnetic wave blocking layer.

11. The plasma processing apparatus of claim 1, wherein the each of the plurality of sensors has a thickness of 2 mm or less, and
wherein the battery is a thin film battery.

12. The plasma processing apparatus of claim 1,
wherein the support portion is configured to support the sensor apparatus.

13. The plasma processing apparatus of claim 12, wherein the support portion includes a chuck configured to fix the sensor apparatus, and
wherein the chuck is configured to move in a first direction.

14. The plasma processing apparatus of claim 13, wherein the support portion further includes an edge ring surrounding an outside of the chuck, the edge ring being configured to move in the first direction.

15. The plasma processing apparatus of claim 13, wherein the chuck is partitioned into a plurality of areas, and
wherein a temperature of each of the plurality of areas is controlled.

16. The plasma processing apparatus of claim 1, wherein the head portion includes a plurality of through holes configured to inject gas that generates the plasma into the chamber.

17. The plasma processing apparatus of claim 16, wherein the plurality of through holes are partitioned into a plurality of areas, and
wherein each injection amount of the gas in each of the plurality of areas is controlled.

18. A plasma processing apparatus comprising:
a chamber;
a sensor apparatus for analyzing plasma in the chamber;
a chuck in the chamber, the chuck being configured to support the sensor apparatus;
an edge ring surrounding an outside of the chuck; and
a head portion disposed to face the chuck, the head portion being configured to inject a gas that generates plasma into the chamber; and
wherein the plasma is generated between the support portion and the head portion,
wherein the sensor apparatus comprising:
a first substrate;
a second substrate on the first substrate; and
a plurality of sensors between the first substrate and the second substrate, the plurality of sensors being spaced apart from each other, wherein each of the plurality of sensors includes:
a sensing assembly that includes a wavelength selector on which light emitted from the plasma is incident and that is configured to separate wavelengths of a spectrum of the light, and a spectrometer that is optically connected to the wavelength selector and configured to detect the spectrum for each separated wavelength; and
a battery connected to the sensing assembly and configured to supply first power to the sensing assembly.

19. The plasma processing apparatus of claim 18, wherein a density of the plasma is controlled by controlling at least one of a distance between the chuck and the head portion, a temperature of the chuck, a position of the edge ring, and an injection amount of the gas.
